(19) United States
(12) Patent Application Publication
(10) Pub. No.: US 2020/0365788 A1
(43) Pub. Date: Nov. 19, 2020

(54) WAFER-LEVEL CHIP-SCALE PACKAGING STRUCTURE AND METHOD OF PREPARING SAME

(71) Applicant: DURA-CHIP (NANTONG) LIMITED, Nantong (CN)

(72) Inventors: Zhijiang SUN, Reno, NV (US); Shuchang WANG, Nantong (CN); Aijie FAN, Nantong (CN)

(21) Appl. No.: 16/908,546

(22) Filed: Jun. 22, 2020

Related U.S. Application Data
(63) Continuation of application No. PCT/CN2018/123064, filed on Dec. 24, 2018.

(30) Foreign Application Priority Data
Dec. 22, 2017 (CN) 201711407800.5
Oct. 16, 2018 (CN) 201811202918.9

(51) Int. Cl. H01L 33/64; H01L 33/00; H01L 33/50

(52) U.S. Cl. CPC H01L 33/642; H01L 33/0095; H01L 2933/0075; H01L 33/508; H01L 2933/0041; H01L 33/505

(57) ABSTRACT

A wafer-level chip-scale packaging structure, including a chip and a first fluorescent layer provided on light-emitting surfaces of the chip. The chip and the first fluorescent layer form a package body A. Less than 10% of an area of the light-emitting surfaces on a side surface of the chip are covered by the first fluorescent layer. A second fluorescent layer that is translucent or transparent is provided on a top surface and a side surface of the package body A to form a package body B. The concentration by weight of the fluorescent powder in the first fluorescent layer is higher than that in the second fluorescent layer. A method of preparing the wafer-level chip-scale packaging structure is also disclosed herein.

### CROSS-REFERENCE TO RELATED APPLICATIONS

This application is a continuation of International Patent Application No. PCT/CN2018/123064, filed on Dec. 24, 2018, which claims the benefit of priority from Chinese Patent Application No. 201711407800.5, filed on Dec. 22, 2017; and No. 201811202918.9, filed on Oct. 16, 2018. The content of the aforementioned applications, including any intervening amendments thereto, is incorporated herein by reference.

### TECHNICAL FIELD

The present application relates to semiconductor packaging technique, and more particularly to a wafer-level chip-scale packaging structure and a method of preparing the same.

### BACKGROUND

Light-emitting diodes (LEDs) are widely used in various fields, such as automotive and indoor lighting, traffic lights, screen display and LCD backlight, because they have small size, long service life, low energy consumption with less impact on the environment, quick response and good firmness and durability. LED is an ideal alternative to traditional light sources. Fluorescent powder is usually mixed with package adhesive and then packaged in LED to change the color of the light emitted by LED. Generally, there are several types of LED package, for example, in-line package (LAMP), surface mount device (SMD), Chip On Board (COB) package and Chip Scale Package (CSP). The LAMP is first developed and commonly applied to low-end lighting display devices. The surface mount package emerged around 2008. The COB package was first promoted by Toshiba Corporation and then became popular in China after 2010. CSP was born in recent years based on the development of the flip chip technique and mass-produced by commercialization after 2015. The development of the packaging technique is found in Wang Jietian, Status and Development of LED Packaging technique [J]. Technology Innovation and Application, 2017(12): 42.

In the COB package, the LED chip is directly fixed on a PCB board using an electrically conductive glue or an insulating glue; wire welding is performed to connect the LED chip and circuits; and a colloid containing the fluorescent powder package is performed. FIG. 8 illustrates the main processes of the COB package technique.

Recently, increasing research has been conducted to optimize LED in device materials, chip process and packaging technique. A novel CSP technique is born based on the gradually mature flip chip technique and diverse techniques of fluorescent powder coating. A CSP light source refers to a type of LED device using the CSP technology, which adopts the fluorescent powder or a film of fluorescent colloid to wrap the flip chip structure, removing most of the packaging steps and simplifying the structure of the traditional LED light source and thus the package body is reduced to ⅕ - 1/10 of the original size. However, the conventional CSP light source technique usually includes the steps of cutting the wafer into pieces; sorting and rearranging the light-emitting chips; and laminating and spraying the fluorescent powder or the fluorescent colloid, resulting in thick and opaque layer of the fluorescent colloid. In addition, this conventional technique involves the cumbersome process and high manufacturing cost. The thick layer of the fluorescent powder or the fluorescent colloid will cause poor heat dissipation performance of the light-emitting chip. The smaller a distance between the pieces of the light-emitting chip, the greater precision re-cutting and re-separating the light-emitting chip covered with the fluorescent powder or the fluorescent colloid requires. Moreover, it is often difficult to spray enough powder at one time or extremely high precision is required to control the amount of powder being sprayed. These problems will increase the device cost and greatly reduce the reliability and uniformity of the device.

The following are four main problems that the conventional CSP light source technique faces.

1) It is hard to mount the CSP light source and weld elements on the board. Since the distance between the positive and negative electrodes of the chip is only 90-200 μm, it is prone to the twist or tilt of the CSP light source. Thus, the precision of the Surface Mount Technique (SMT) is highly required. Specifically, the chip and the solder paste are required to be accurately aligned to reduce the risk of the electric leakage and the occurrence of the open circuit. In addition, the fluorescent powder of the CSP light source is opaque, so it is hard to know whether the chips are arranged regularly in the package body or how much the chips are shifted, which greatly increases the difficulty of the mounting and fails to allow the chips and the pad to be accurately positioned, as shown in FIGS. 9 and 10 (the chip core is shown in the line frame).

2) The colloid on a side surface of the CSP light source generally has a non-uniform width, which leads to non-uniform light color or even the occurrence of yellow borders in some products, as shown in FIG. 11. The irregular arrangement of the chips and the cutting errors impart the non-uniform thickness to the glue on the side surface of the CSP light source, affecting the uniformity of the light emitted from the sides, as shown in FIG. 12. At the same time, high precision required by the mounting, and the high cost and low production capacity of the cutting device are involved.

3) It is hard to uniformly distribute the fluorescent powder, and to control a uniform width of the colloid and the uniformity of the light emitted from the side surface of the CSP light source, causing a small proportion of the LEDs within the bin ranges after coating once, as shown in FIG. 13.

4) The thick layer of the fluorescent powder impedes the heat dissipation. Under the high optical density, LED chips generate lots of heat, besides, the fluorescent powder also generates a large amount of heat while emitting yellow-green light during the light conversion, and thus good heat dissipation performance is highly required. When the fluorescent colloid is thick, heat is difficultly dissipated from the chip. The study found that when the surface temperature of the CSP light source reaches more than 150° C., the light efficiency of the light source significantly decreases, and the fluorescent colloid is prone to cracking. In addition, the thick layer of the fluorescent powder causes the occurrences of the yellow borders, and the thin layer of the fluorescent powder causes the problems in mounting and cutting. Moreover, the limited precision of the device will cause an error range of about 30 μm during the mounting and cutting, and thus the thin layer of the fluorescent powder will lead to the non-uniform thickness of the layer of the fluorescent powder on the side walls of the chip, causing nonuniformity of the light color and the leakage of the blue light.

Currently, the CSP light source has two limitation in application due to the four problems mentioned above. First, it is difficult to mount small-size CSP light sources, so the CSP light sources are currently only applied to the product having a power of more than 1 W; second, the high cost of the CSP light source limits the application to the light sources with high optical density, high brightness and high directivity, like car lights, flashlights, backlights and high-end lighting device with adjustable color temperature. Therefore, it is hard to further broaden the application ranges.

### SUMMARY

This application aims to provide a wafer-level chip-scale packaging structure and a method of preparing the same, so as to improve the heat dissipation performance of a light-emitting chip, reduce the manufacturing cost of the light-emitting chip and improve the reliability and uniformity of the light-emitting chip.

The technical solutions of the application are described as follows.

The application provides a wafer-level chip-scale packaging structure, comprising a chip and a first fluorescent layer which is provided on a top light-emitting surface and a side light-emitting surface of the chip, respectively;

wherein less than 10% of an area of the side light-emitting surface is covered by the first fluorescent layer; the chip and the first fluorescent layer form a package body A;

a second fluorescent layer that is translucent or transparent is provided on a top surface and a side surface of the package body A; and the package body A and the second fluorescent layer form a package body B;

a concentration by weight of fluorescent powder in the first fluorescent layer is set as w1; a concentration by weight of the fluorescent powder in the second fluorescent layer is set as w2; and w1 is larger than w2;

the first fluorescent layer on the top light-emitting zone has a uniform thickness; the second fluorescent layer on the top surface of the package body A has a uniform thickness; and the package body B is a cuboid.

In an embodiment, the first fluorescent layer and the second fluorescent layer each are prepared from a fluorescent colloid.

In an embodiment, the first fluorescent layer comprises 50%-90% by weight of the fluorescent powder; and the second fluorescent layer comprises 0-40% by weight of the fluorescent powder.

The application further provides a method of preparing the wafer-level chip-scale packaging structure, comprising:

1) attaching a film on a wafer; cutting the wafer into pieces; and forming a basic fluorescent layer on all the wafer pieces; or

forming a basic fluorescent layer on a wafer; attaching a film on the wafer covered with the basic fluorescent layer; and cutting the wafer into pieces;

2) spreading the basic fluorescent layer to form the first fluorescent layer which together with the chip forms the package body A; wherein a difference between a length of a side of the top surface of the package body A and a length of a corresponding side of the top light-emitting surface of the chip is less than 30 μm;

3) baking and curing the wafer covered with the first fluorescent layer;

4) testing chips in the baked and cured wafer; and sorting and rearranging the chips according to test results;

5) forming the second fluorescent layer that is translucent or transparent on the sorted and rearranged chips; and baking and curing the chips covered with the second fluorescent layer;

6) cutting the sorted and rearranged chips obtained in step (4) followed by performing step (5) to form wafer-level chip-scale packaging structures; or

cutting the baked and cured chips obtained in step (5) to form wafer-level chip-scale packaging structures.

In an embodiment, the method further comprises:

determining a position of the first fluorescent layer from an outside of each wafer-level chip-scale packaging structure formed in step (6) based on a concentration difference between the first fluorescent layer and the second fluorescent layer; performing a chip bonding test on each wafer-level chip-scale packaging structure according to the position of the first fluorescent layer; and packing and storing wafer-level chip-scale packaging structures that pass the chip bonding test.

In an embodiment, before step (2), the basic fluorescent layer is in a non-cured state.

In an embodiment, a thickness of the first fluorescent layer is 150 μm or less; a thickness of the second fluorescent layer on the top surface of the package body A is 10-1000 μm, and a thickness of the second fluorescent layer on a side surface of the package body A is 10-2000 μm.

In an embodiment, each chip is a cuboid; and after the second fluorescent layer is formed, a distance of adjacent chips is greater than a length or a width of the chip.

In an embodiment, in step (6), the step of cutting the sorted and rearranged chips comprises:

placing a wire mesh fixture on the sorted and rearranged chips for uniformly cutting the chips.

In an embodiment, in step (5), the second fluorescent layer is formed by coating, laminating or injection molding.

Compared to the prior art, the wafer-level chip-scale packaging structure and the method of preparing the same of the application have the following advantages.

1) In the wafer-level chip-scale packaging structure, the first fluorescent layer has a high concentration by weight of the fluorescent powder. The formed fluorescent layer is thin, highly dense and has a similar size to the chip, which allows the heat to be better dissipated, reduces the risk of the cracking of the colloid and improves the light efficiency of the chip. The second fluorescent layer has a low concentration by weight of the fluorescent powder and is translucent or transparent. Such design benefits two aspects as follows. On one hand, the subsequent processes can produce a large distance between adjacent chips to reduce the precision requirements for cutting and separating the chip covered with the fluorescent powder or the fluorescent colloid, thereby improving the reliability and uniformity of the device. On the other hand, when the positive and negative electrodes on the bottom of the two-layer wafer-level chip-scale packaging (WLCSP) structure are required to be accurately aligned to the positive and negative electrodes on the substrate, the subsequent processes such as the chip bonding and electrode alignment can be accurately performed by observing through the second fluorescent layer that is translucent or transparent and utilizing the characteristics of the first fluorescent layer that is not transparent and has the same profile as the chip, thereby reducing the process difficulty and further decreasing the manufacturing cost of the device.

2) The method of preparing the wafer-level chip-scale packaging structure includes the steps of forming the fluorescent layer twice in wafer-level and chip-scale in sequence, and the formed the fluorescent layer has a dense surface. Where, after forming the first fluorescent layer, the chips are spread, baked for curing, tested and rearranged. The fluorescent powder is sprayed on the first fluorescent layer to form the second fluorescent layer followed by cutting the chip into pieces, etc. The method of the application has simple and stable processes and greatly improved yield in manufacturing the device.

3) In the method of preparing the wafer-level chip-scale packaging structure, before being spread, the basic fluorescent layer is in a non-cured state, which helps to separate the chips and perform the subsequent processes such as the chip testing and rearrangement.

### BRIEF DESCRIPTION OF THE DRAWINGS

This application will be further described in detail with reference to the accompanying drawings and the embodiments.

FIG. 1 is a schematic diagram of a wafer-level chip-scale packaging structure according to the present application.

FIG. 2 is a cross-sectional view of a wafer-level chip-scale packaging structure after covered with a first fluorescent layer.

FIG. 3 is a bottom view of the wafer-level chip-scale packaging structure covered with the first fluorescent layer.

FIG. 4 is a cross-sectional view of a wafer-level chip-scale packaging structure covered with a second fluorescent layer.

FIGS. 5A-B are top views showing a wafer-level chip-scale packaging structure covered with a second fluorescent layer assisted by a wire mesh fixture.

FIG. 6 is a cross-sectional view of a wafer-level chip-scale packaging structure covered with a second fluorescent layer by laminating.

FIG. 7 is a cross-sectional view of a wafer-level chip-scale packaging structure covered with a second fluorescent layer by injection molding.

FIG. 8 is a flow chart showing main processes of the COB packaging technique.

FIGS. 9 and 10 show the inappropriate mounting caused by the failure of accurately aligning the chips in the conventional CSP light source.

FIG. 11 shows the occurrence of yellow borders caused by non-uniform light color of the chips in the conventional CSP light source.

FIG. 12 shows the non-uniform thickness of a colloid on a side surface of the CSP caused by the cutting error.

FIG. 13 is a test data graph showing the proportion of LEDs within the bin ranges.

FIG. 14 is a schematic view of a conventional CSP light source.

FIG. 15 is another schematic diagram of a wafer-level chip-scale packaging structure according to the present application.

FIG. 16 shows microphotographs of the mounting of the chips in the wafer-level chip-scale packaging structure according to the present application.

FIGS. 17A-B are a cross-sectional view of a conventional CSP light source and a scanning electron micrograph thereof, respectively.

FIGS. 18A-B are a cross-sectional view of the wafer-level chip-scale packaging structure according to the present application and a scanning electron micrograph thereof, respectively.

FIG. 19 shows a light-emitting effect of the conventional CSP light source.

FIG. 20 shows a light-emitting effect of the wafer-level chip-scale packaging structure according to the present application.

FIG. 21 is a test chart of color temperatures of the conventional CSP light source at spatial angles.

FIG. 22 is a test chart of color temperatures of the wafer-level chip-scale packaging structure at spatial angles according to an embodiment.

FIG. 23 is a test chart of color temperatures of the wafer-level chip-scale packaging structure at spatial angles according to another embodiment.

### DETAILED DESCRIPTION OF EMBODIMENTS

The following embodiments are illustrative to make those skilled in the art fully understand the present application and are not intended to limit the application.

### Embodiment 1

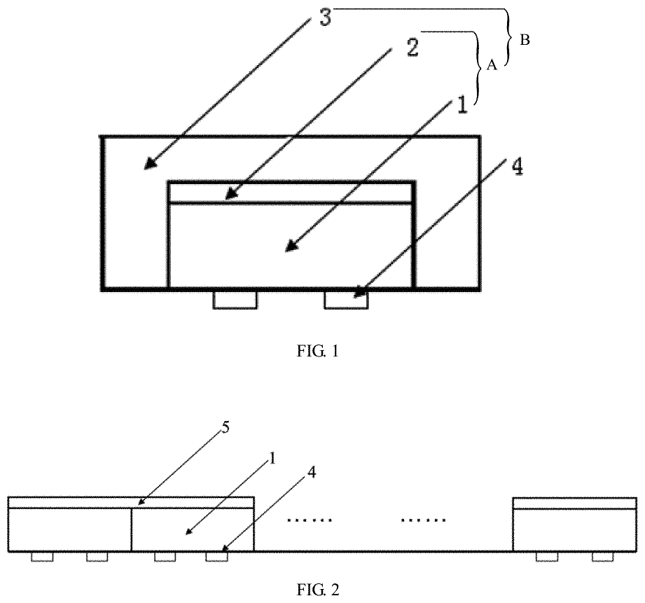

This embodiment provides a wafer-level chip-scale packaging structure, as shown in FIG. 1, including a chip 1 and chip electrodes 4 provided on the chip 1. A first fluorescent layer 2 is provided on a top light-emitting surface and a side light-emitting surface of the chip 1, respectively. Less than 10% of an area of the side light-emitting surface is covered by the first fluorescent layer 2; the chip 1 and the first fluorescent layer 2 form a package body A; a second fluorescent layer 3 that is translucent or transparent is provided on a top surface and a side surface of the package body A; the package body A and the second fluorescent layer form a package body B; a concentration by weight of fluorescent powder in the first fluorescent layer 2 is set as w1; a concentration by weight of the fluorescent powder in the second fluorescent layer 3 is set as w2; w1 is larger than w2; the first fluorescent layer 2 on the top light-emitting surface has a uniform thickness; the second fluorescent layer 3 on the top surface of the package body A has a uniform thickness; and the package body B is a cuboid.

In the embodiment, the second fluorescent layer 3 (simply called “hemline” below) that is translucent or transparent and the chip 1 (simply called “core” below for understanding) inside the second fluorescent layer 3 are identified and distinguished by comparing the grey scale of the hemline and the core through an image recognition technique using a LED mounting device. The image recognition technique is well known to those skilled in the art. Given this, the working principle of the image recognition technique will not be described in detail herein.

When the absolute value of a difference between the grey scale of the hemline and the grey scale of the core is greater than or equal to 30, a boundary between the core and the hemline can be easily identified by the LED mounting device, indicating that the second fluorescent layer 3 is transparent or translucent;

when the absolute value of a difference between the grey scale of the hemline and the grey scale of the core is less than 30, the boundary between the core and the hemline cannot be easily identified by the LED mounting device, indicating the second fluorescent layer 3 is opaque.

The standard of whether the process of identifying is easy depends on the probability that the LED mounting device successfully recognizes the boundary between the core and the hemline, that is, the probability of 99.5% or even higher indicates that the LED mounting device can easily identify the boundary in the mass industrial production.

For example, when the transparency recognition is performed through the image recognition technique using the LED mounting device, in the case that a concentration ratio of the fluorescent powder to silica gel to a solvent in the second fluorescent layer 3 is 0.35:1:0.5, and the LED mounting device calculates the gray value of the core and the hemline to be 255 and 200 in binary, respectively, the probability that the LED mounting device successfully recognizes the core is greater than 99.5%; by further adjusting the concentration ratio of the fluorescent powder to the silica gel to the solvent in the second fluorescent layer 3, when the LED mounting device calculates the gray value of the core and the hemline to be 255 and 225, respectively, the probability that the LED mounting device successfully recognizes the core is 99.5%, indicating the second fluorescent layer 3 is translucent; in the case that a concentration ratio of the fluorescent powder to the silica gel to the solvent in the second fluorescent layer 3 is 0.6:1:0.5, and the LED mounting device calculates the gray value of the core and the hemline to be 255 and 240 in binary, respectively, the probability that the LED mounting device successfully recognizes the core is only 15%, indicating the second fluorescent layer 3 is opaque.

In the embodiment, the first fluorescent layer 2 and the second fluorescent layer 3 each are prepared from a fluorescent colloid. The first fluorescent layer 2 includes 50%-90% by weight of the fluorescent powder; and the second fluorescent layer 3 includes 0-40% by weight of the fluorescent powder. A thickness of the first fluorescent layer 2 is 150 μm or less; a thickness of the second fluorescent layer 3 on the top surface of the package body A is 10-1000 μm, and a thickness of the second fluorescent layer 3 on the side surface of the package body A is 10-2000 μm. In the embodiment, an upper part of the side light-emitting surface of the chip 1 is covered by a small amount of the first fluorescent layer 2. Specifically, less than 10% of the area of the side light-emitting surface is covered by the first fluorescent layer 2. The chip 1 is a cuboid; and after the second fluorescent layer 2 is formed, a distance of adjacent chips is greater than a length or a width of the chip 1.

The wafer-level chip-scale packaging structure of the embodiment is prepared by the following steps.

1) As shown in FIG. 1, a wafer is attached with a film and then cut into pieces. Subsequently, all the wafer pieces are covered with the fluorescent colloid which includes 50%-90% by weight of the fluorescent powder, so that a basic fluorescent layer 5 is directly formed on the wafer in whole, naturally, all chips 1 in the wafer are also covered with the basic fluorescent layer 5; or

as shown in FIG. 2, a wafer is sprayed with the fluorescent colloid which includes 50%-90% by weight of the fluorescent powder, so that a basic fluorescent layer 5 is directly formed on the wafer in whole, naturally, all chips 1 in the wafer are also covered with the basic fluorescent layer 5. Subsequently, the wafer covered with the basic fluorescent layer 5 is attached with a film and then cut into pieces.

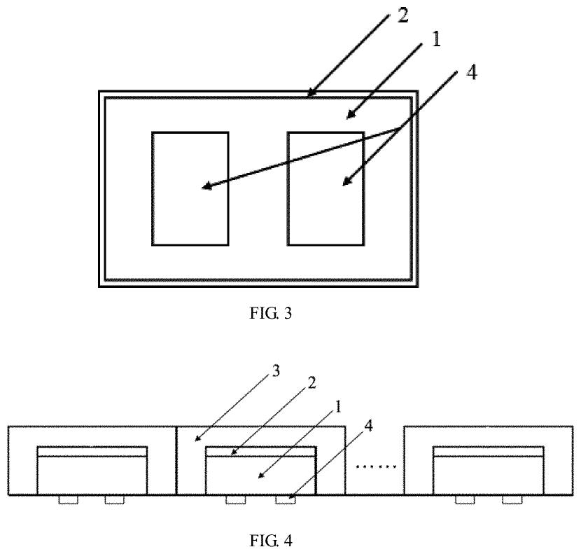

2) The basic fluorescent layer 5 applied on the wafer is spread to form the first fluorescent layer 2 which together with the chip 1 forms the package body A, as shown in FIG. 3, where a thickness of the first fluorescent layer is 150 μm or less; before being spread, the basic fluorescent layer is in a non-cured state, and a difference between a length of a side of the top surface of the package body A and a length of a corresponding side of the top light-emitting surface of the chip 1 is less than 30 μm.

3) The wafer obtained in step (2) is baked and cured at a temperature of 30-200° C. for 3-12 h.

4) The chips 1 in the baked and cured wafer are tested in photoelectric parameters, such as the brightness, the color-rendering index and the color temperature, and then the chips 1 are sorted and rearranged according to test results.

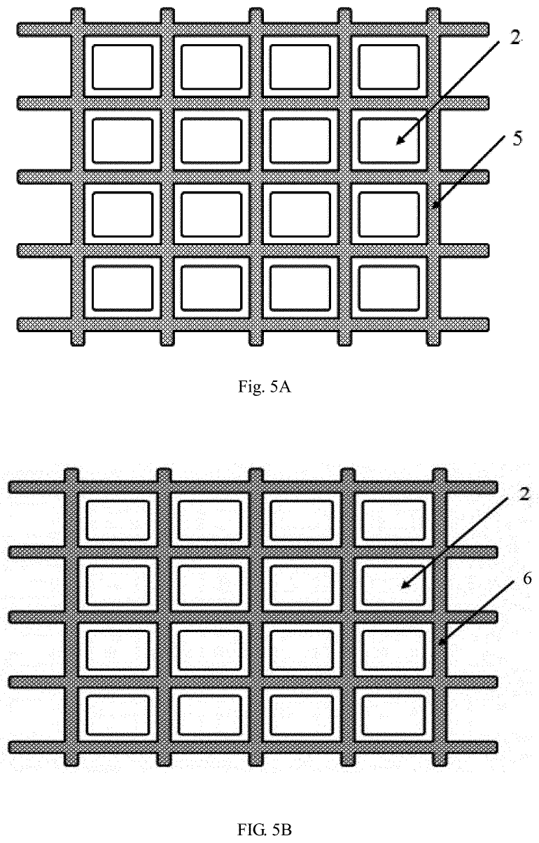

5) As shown in FIG. 4, the sorted and rearranged chips 1 are sprayed with the fluorescent colloid which includes 0-40% by weight of the fluorescent powder to form the second fluorescent layer 3 that is translucent or transparent, where a thickness of the second fluorescent layer 3 on the top surface of the package body A is 10-1000 μm, and a thickness of the second fluorescent layer on the side surface of the package body A is 10-2000 μm. Subsequently, the chip 1 coated with the second fluorescent layer 3 is baked and cured at a temperature of 30-200° C. for 3-12 h, where the chip 1 is a cuboid; and a distance of adjacent chips is greater than a length or a width of the chip 1.

6) The baked and cured chip obtained in step (5) is cut to form wafer-level chip-scale packaging structures.

After the above steps, a position of the first fluorescent layer 2 is observed from an outside of each wafer-level chip-scale packaging structure obtained in step (6) based on a concentration difference between the first fluorescent layer 2 and the second fluorescent layer 3. Each wafer-level chip-scale packaging structure is subjected to a chip bonding test based on the position of the first fluorescent layer 2. Wafer-level chip-scale packaging structures that pass the chip bonding test are bagged and stored.

### Embodiment 2

This embodiment has the same wafer-level chip-scale packaging structure as Embodiment 1. However, in the embodiment, the preparation method of the wafer-level chip-scale packaging structure has different steps (5) and (6). In step (5) of the embodiment, as shown in FIG. 5, before applying the second fluorescent layer 3, a wire mesh fixture 6 is placed on the sorted and rearranged chips 1 for uniformly cutting the chips 1 followed by spraying a fluorescent colloid which includes 0-40% by weight of the fluorescent powder, so as to form the second fluorescent layer 3 that is translucent or transparent, where a thickness of the second fluorescent layer 3 on the top surface of the package body A is 10-1000 μm, and a thickness of the second fluorescent layer on the side surface of the package body A is 10-2000 μm. Subsequently, the chips 1 covered with the second fluorescent layer 3 are baked and cured again at a temperature of 30-200° C. for 3-12 h, where each chip 1 is a cuboid; and a distance of adjacent chips is greater than a length or a width of the chip 1. In step (6) of the embodiment, wafer-level chip-scale packaging structures are formed after the chips 1 are baked and cured again in step (5).

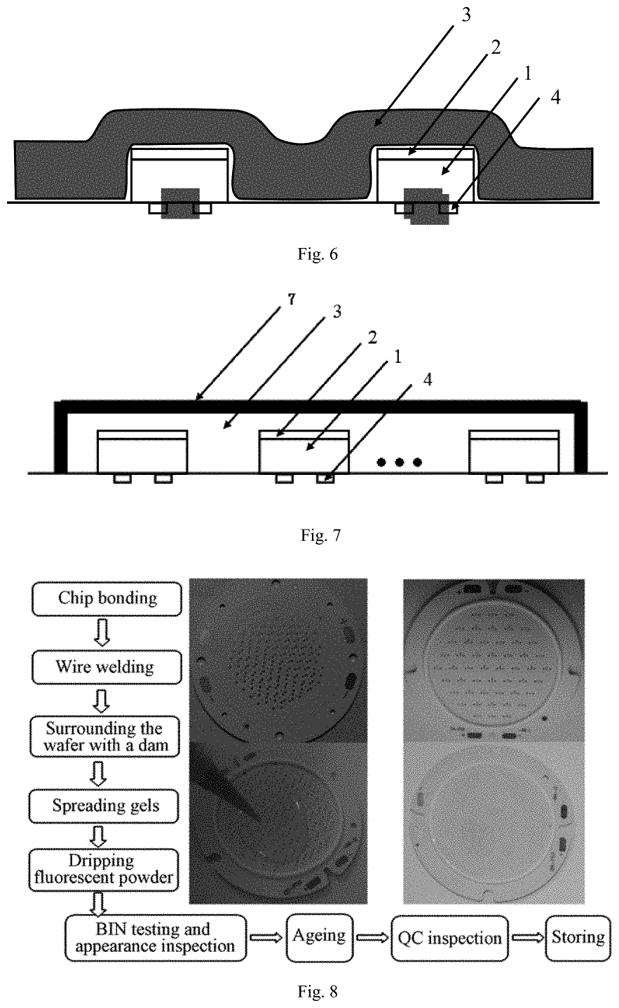

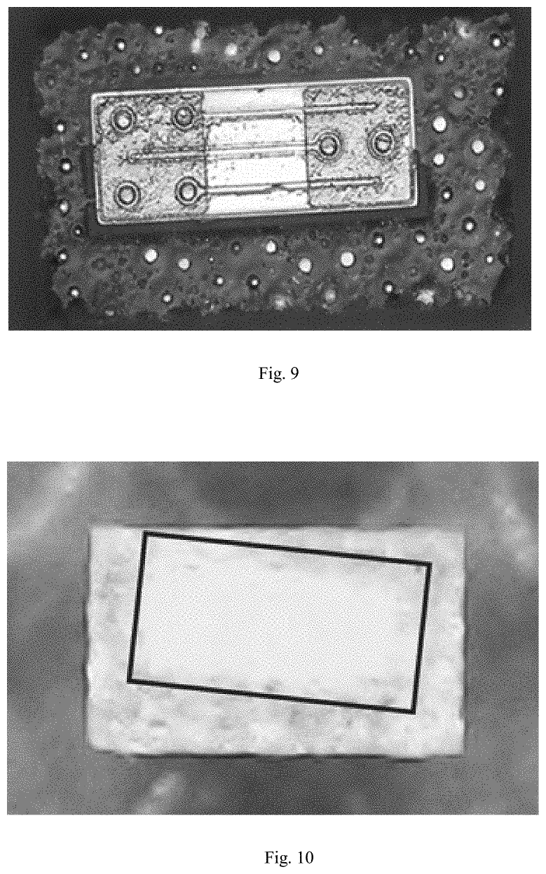

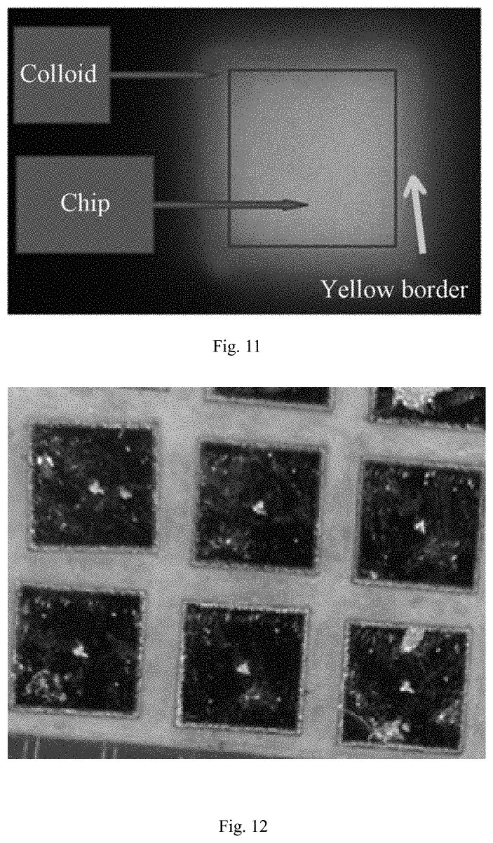

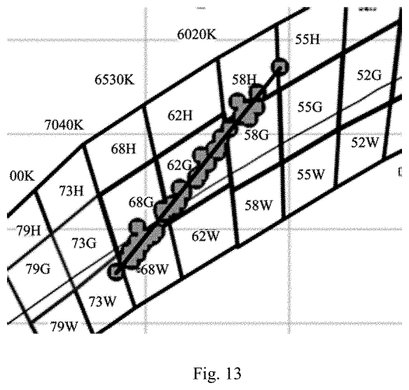

In the embodiments, the second fluorescent layer 3 can be formed by laminating or injection molding. FIG. 6 shows a wafer-level chip-scale packaging structure, in which the second fluorescent layer is formed by laminating. The following are the specific steps of the laminating. The silica gel and the fluorescent powder are mixed in proportion to form the fluorescent colloid having 0-40% by weight of the fluorescent powder. Subsequently, the fluorescent colloid is poured into a mold followed by baking and curing to obtain a fluorescent film. Then the fluorescent film is tightly attached to surfaces of the sorted and rearranged chips 1 followed by curing again, so as to form the second fluorescent layer 3. The second fluorescent layer 3 formed by laminating has a controllable shape, a uniform thickness and the high stability.

The following are the specific steps of the injection molding. A mold 7, as shown in FIG. 7, is nested on the sorted and rearranged chips 1, and then the fluorescent powder and the silica gel are mixed in proportion to form the fluorescent colloid having 0-40% by weight of the fluorescent powder. Subsequently, the fluorescent colloid is poured into the mold 7 followed by baking and curing. After curing, the mold 7 is removed to form the second fluorescent layer 3 which is hardened and stable. Finally, the chips 1 covered with the second fluorescent layer 3 are cut to obtain wafer-level chip-scale packaging structures.

Compared to the conventional CSP light source, the wafer-level chip-scale packaging structure prepared in the above embodiments extends the packaging process and the chip process to the upstream chip process. Specifically, the wafer is packaged to form the core that is opaque, and the core is surrounded by the second fluorescent layer 3 that is translucent, which effectively solves the above problems that the conventional CSP light source has, realizing the technical improvement of the conventional CSP light source.

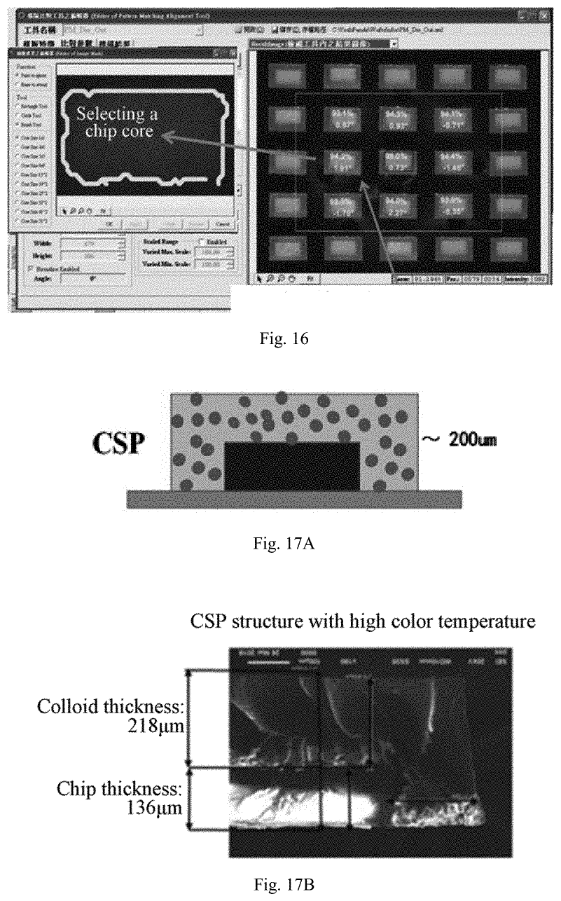

A chip bonder mainly includes a personal computer (PC)-based control system and a Pattern Recognition System (PRS), which are separately controlled by two hosts. For the CSP light source, precise mounting can be realized only when the chip inside the structure is accurately identified. The second fluorescent layer 3 coated in the wafer-level chip-scale packaging structure of the application is translucent or transparent to greatly help the chip bonder efficiently and accurately identify a position of the chip inside the wafer-level chip-scale packaging structure, so as to control a distance between the light source and the substrate with higher accuracy. Since the conventional CSP light source has the layer of the fluorescent powder that is opaque, during the chip bonding, the chip bonder fails to accurately identify the chip inside the wafer-level chip-scale packaging structure, which greatly reduces the chip mounting yield, thereby increasing the risk of electrical leakage and greatly reducing the reliability of the light source. The wafer-level chip-scale packaging structure of the application can be applied to the filament bulb with adjustable color temperature, where even two different CSP light sources can be mounted within one millimeter, displaying the ability of precise mounting, as shown in FIG. 16, the mounting can be efficiently performed when the chip inside the wafer-level chip-scale packaging structure is accurately identified.

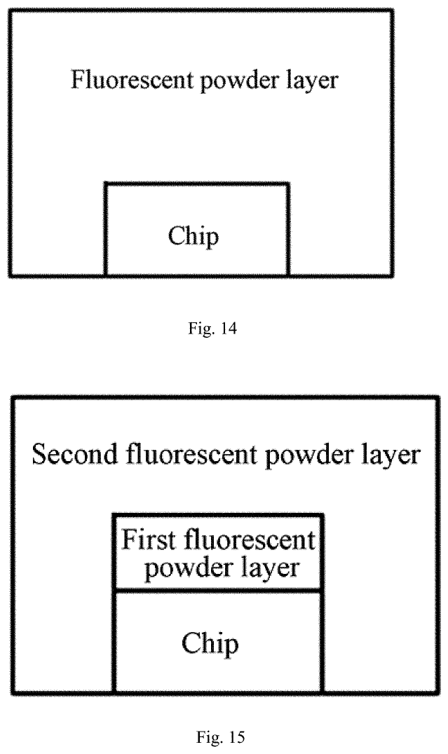

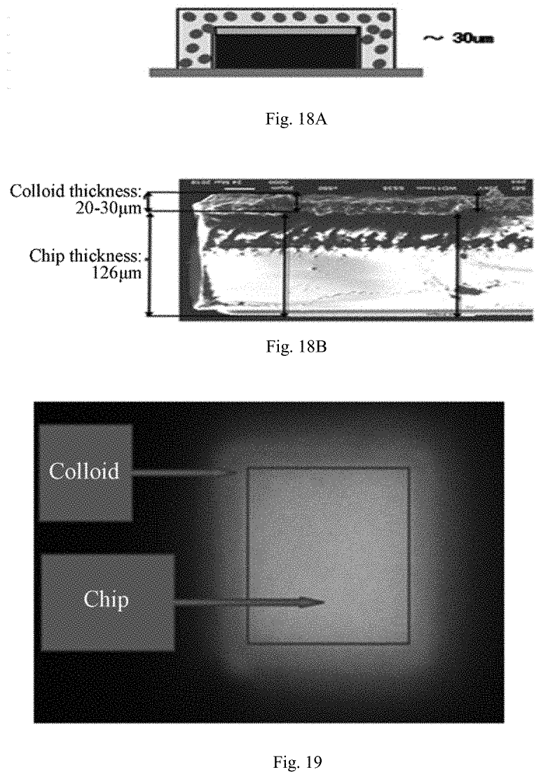

Further, the wafer-level chip-scale packaging structure of the application has a thinner layer of the fluorescent powder, greatly improving the heat dissipation performance and effectively avoiding the difficulties in the cutting and mounting caused by the large thickness that the conventional CSP light source has. FIGS. 14 and 15 respectively show the packaging structure of the conventional CSP light source and the wafer-level chip-scale packaging structure of the application.

Where, it is known that, under high optical density, LED chips usually generate lots of heat, in fact, the layer of the fluorescent powder also generates a large amount of heat while emitting yellow-green light during the light conversion, and thus the good heat dissipation performance is highly required. The thick layer of the fluorescent powder impedes the heat dissipation of the chip. For example, when the power reaches more than 4 W, the surface temperature of the chip will reach more than 150° C., resulting in a reduced light efficiency and the cracking of the colloid in the layer of the fluorescent powder. In the wafer-level chip-scale packaging structure of the application, the wafer is sprayed with the fluorescent powder for the first time to form the first fluorescent layer 2, so that the fluorescent powder can be easily precipitated downward to form a dense layer. Scanning Electron Micrographs in FIGS. 17 and 18 show particles of the fluorescent powder which are closely arranged. Therefore, when the fluorescent powder absorbs about 70% of the blue light, the light is quickly conducted downward by the fluorescent powder. However, in the conventional CSP light source, the fluorescent powder is mixed with the silica gel which has a thermal conductivity of only 0.2-0.7. After absorbing heat, the fluorescent powder is continuously excited by blue light to generate heat, but the generated heat is difficultly conducted to the outside of the structure. In the same conditions, the surface temperature of the chip 1 in the wafer-level chip-scale packaging structure of the application is only 110-120° C., indicating that heat is well dissipated from the chip 1.

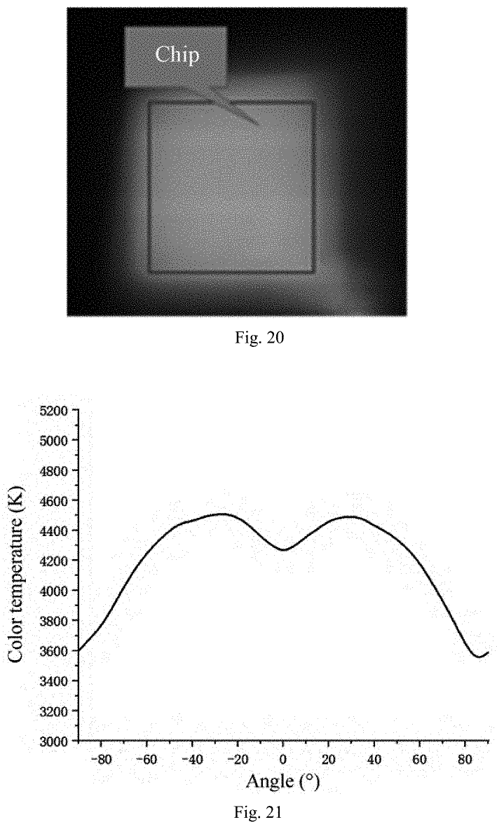

Further, the light emitted from the wafer-level chip-scale packaging structure of the application has uniform color. The chip in the conventional CSP light source has a top light-emitting surface and a side light-emitting surface. 70% of an area of the top surface of the chip is the top light-emitting surface, and 30% of an area of a side surface of the chip is the side light-emitting surface. Since the top surface of the chip 1 is sprayed with the fluorescent powder with a certain concentration, when 70% of the area of the top surface of the chip is the top light-emitting surface for emitting the blue light, white light is emitted from the structure. Since a side surface of the chip is sprayed with the fluorescent powder with the same concentration by weight, when 30% of the area of the side surface of the chip is the side light-emitting surface for emitting the blue light, the light emitted from a side surface of the structure is faintly yellow, especially a corresponding side edge of the structure is obviously yellow, as shown in FIG. 19. However, the wafer-level chip-scale packaging structure of the application has the first fluorescent layer on the top surface of the chip and the second fluorescent layer on the side surface of the chip, where the first fluorescent layer has a high concentration of the fluorescent powder and the second fluorescent layer has a low concentration of the fluorescent powder, so when 30% of the area of the side surface of the chip is the side light-emitting surface for emitting the blue light, and the concentration of the fluorescent powder in the second fluorescent layer is about 20%-30% of the concentration of the fluorescent powder in the first fluorescent, the light emitted from the top surface and side surface of the chip 1 has uniform color, as shown in FIG. 20. The wafer-level chip-scale packaging structure of the application can effectively avoid the occurrence of leaked blue light and yellow borders which are caused by the non-uniform distribution of the fluorescent powder. In addition, the wafer-level chip-scale packaging structure of the application has the beam angle that can be arbitrarily adjusted, so as to meet various application requirements. The light emitted from the wafer-level chip-scale packaging structure of the application has uniform color.

Where, less than 10% of the area of the side light-emitting surface at an upper part of the chip 1 is covered by a small amount of the first fluorescent layer 2, which further makes the wafer-level chip-scale packaging structure of the application have uniform color temperatures at spatial angles, avoiding the disadvantage of the conventional package body that the color temperatures are not uniform at spatial angles.

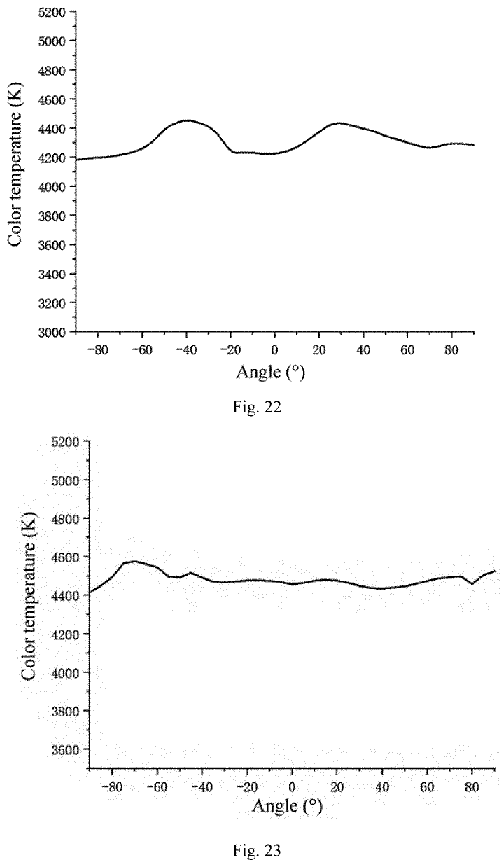

See FIGS. 21-23, FIG. 21 shows the color temperatures of the conventional CSP light source at spatial angles, and it is obvious that the conventional CSP light source has greatly varied color temperatures at spatial angles. FIG. 22 shows the color temperatures of the wafer-level chip-scale packaging structure without the first fluorescent layer 2 on the side light-emitting surface of the chip 1 at spatial angles according to an embodiment, and it is obvious that compared with the conventional CSP light source in FIG. 21, the color temperatures of this wafer-level chip-scale packaging structure has an improved uniformity. FIG. 23 shows the color temperatures of the wafer-level chip-scale packaging structure having the first fluorescent layer 2 that covers 8% of the area of the side light-emitting surface of the chip 1 at spatial angles according to an embodiment, and it is seen that the color temperatures of this wafer-level chip-scale packaging structure barely vary at spatial angles, displaying a greatly improved uniformity of the color temperatures at spatial angles compared with that of the conventional CSP light source in FIG. 21.

Where, when more than 10% of the area of the side light-emitting surface of the chip 1 is covered with the first fluorescent layer 2, due to the opaque first fluorescent layer 2 and the coverage ratio of more than 10%, the first fluorescent layer 2 is largened in size. However, the subsequent processes, such as the chip bonding and electrode alignment, benefit from the characteristics that the first fluorescent layer 2 is not transparent and has the same profile as the chip 1, and the second fluorescent layer 3 is translucent or transparent, thus, increased size of the first fluorescent layer 2 will increase the difficulty of implementing the chip bonding and the electrode alignment, reducing the process accuracy and improving the manufacturing cost of the device. Therefore, it is preferred to control the coverage ratio of the first fluorescent layer 2 on the side light-emitting surface in a range of 0-10%, which can not only significantly improve the uniformity of the color temperature of the chip 1 at spatial angles and have uniform emitted light, but also avoid the adverse impact on the subsequent processes, such as the chip bonding and the electrode alignment, having great practical significance.

Therefore, the wafer-level chip-scale packaging structure of the application and the method of preparing the same can allow the heat to be better dissipated from the chip, reduce the manufacturing cost of the dive and improve the reliability and uniformity of the device, having broad market prospects.

The wafer-level chip-scale packaging structure prepared in Embodiments 1 and 2 has the first fluorescent layer 2 having 50%-90% by weight of the fluorescent powder, and the formed fluorescent layer is thin, highly dense and has a similar size to the chip, which allows the heat to be better dissipated from the chip 1, reduces the risk of the cracking of the colloid and improves the light efficiency of the chip 1. The second fluorescent layer 3 has 0-40% by weight of the fluorescent powder and is translucent or transparent. Such design benefits two aspects as follows. On one hand, the subsequent processes can produce a large distance between adjacent chips to reduce the accuracy requirements of cutting and separating the chip 1 covered with the fluorescent powder or the fluorescent colloid, thereby improving the reliability and uniformity of the device. On the other hand, the second fluorescent powder is translucent or transparent, which is beneficial to accurately perform the subsequent processes such as the chip bonding and the electrode alignment by using the first fluorescent layer 2, reducing the process difficulty and further decreasing the manufacturing cost of the device.

The above shows and describes the basic principles, main features and advantages of the application. It is known to those skilled in the art that the embodiments and the description mentioned above are not intended to limit the application, but merely to illustrate the principles of the application. Any changes and improvements without departing from the spirit of the application shall fall with the scope of the application. The application is limited to the appended claims and equivalents thereof.

What is claimed is:

1. A wafer-level chip-scale packaging structure, comprising a chip and a first fluorescent layer which is provided on a top light-emitting surface and a side light-emitting surface of the chip, respectively;
wherein less than 10% of an area of the side light-emitting surface is covered by the first fluorescent layer; the chip and the first fluorescent layer form a package body A;
a second fluorescent layer that is translucent or transparent is provided on a top surface and a side surface of the package body A; and the package body A and the second fluorescent layer form a package body B;
a concentration by weight of fluorescent powder in the first fluorescent layer is set as w1; a concentration by weight of the fluorescent powder in the second fluorescent layer is set as w2; and w1 is larger than w2;
the first fluorescent layer on the top light-emitting zone has a uniform thickness;
the second fluorescent layer on the top surface of the package body A has a uniform thickness; and the package body B is a cuboid.

2. The wafer-level chip-scale packaging structure of claim 1, wherein the first fluorescent layer and the second fluorescent layer each are prepared from a fluorescent colloid.

3. The wafer-level chip-scale packaging structure of claim 1, wherein the first fluorescent layer comprises 50%-90% by weight of the fluorescent powder; and the second fluorescent layer comprises 0-40% by weight of the fluorescent powder.

4. A method of preparing the wafer-level chip-scale packaging structure of claim 1, comprising:
1) attaching a film on a wafer; cutting the wafer into pieces; and forming a basic fluorescent layer on all the wafer pieces; or
forming a basic fluorescent layer on a wafer; attaching a film on the wafer covered with the basic fluorescent layer; and cutting the wafer into pieces;
2) spreading the basic fluorescent layer to form the first fluorescent layer which together with the chip forms the package body A; wherein a difference between a length of a side of the top surface of the package body A and a length of a corresponding side of the top light-emitting surface of the chip is less than 30 μm;
3) baking and curing the wafer covered with the first fluorescent layer;
4) testing chips in the baked and cured wafer; and sorting and rearranging the chips according to test results;
5) forming the second fluorescent layer that is translucent or transparent on the sorted and rearranged chips; and baking and curing the chips covered with the second fluorescent layer; and
6) cutting the sorted and rearranged chips obtained in step (4) followed by performing step (5) to form wafer-level chip-scale packaging structures; or
cutting the baked and cured chips obtained in step (5) to form wafer-level chip-scale packaging structures.

5. The method of claim 4, wherein the method further comprises:
determining a position of the first fluorescent layer from an outside of each wafer-level chip-scale packaging structure formed in step (6) based on a concentration difference between the first fluorescent layer and the second fluorescent layer;
performing a chip bonding test on each wafer-level chip-scale packaging structure according to the position of the first fluorescent layer; and packing and storing wafer-level chip-scale packaging structures that pass the chip bonding test.

6. The method of claim 4, wherein before step (2), the basic fluorescent layer is in a non-cured state.

7. The method of claim 4, wherein a thickness of the first fluorescent layer is 150 μm or less; a thickness of the second fluorescent layer on the top surface of the package body A is 10-1000 μm, and a thickness of the second fluorescent layer on a side surface of the package body A is 10-2000 μm.

8. The method of claim 4, wherein each chip is a cuboid; and after the second fluorescent layer is formed, a distance of adjacent chips is greater than a length or a width of the chip.

9. The method of claim 4, wherein in step (6), the step of cutting the sorted and rearranged chips comprises:
placing a wire mesh fixture on the sorted and rearranged chips for uniformly cutting the chips.

10. The method of claim 4, wherein in step (5), the second fluorescent layer is formed by coating, laminating or injection molding.
